(19) United States
(12) Patent Application Publication
(10) Pub. No.: US 2020/0057329 A1
(43) Pub. Date: Feb. 20, 2020

(54) THIN FILM TRANSISTOR ARRAY SUBSTRATE AND MANUFACTURING METHOD OF SAME

(71) Applicant: Wuhan China Star Optoelectronics Semiconductor Display Technology Co., Ltd., Wuhan (CN)

(72) Inventors: Peihong LI, Wuhan (CN); Jiangjiang SONG, Wuhan (CN)

(73) Assignee: Wuhan China Star Optoelectronics Semiconductor Display Technology Co., Ltd., Wuhan (CN)

(21) Appl. No.: 16/342,544

(22) PCT Filed: Sep. 13, 2018
(86) PCT No.: PCT/CN2018/105545

§ 371 Date: Apr. 17, 2019

(30) Foreign Application Priority Data
Aug. 20, 2018 (CN) 201810948985.9

(51) Int. Cl. G02F 1/1362; G02F 1/1333; H01L 27/12

(52) U.S. Cl. CPC G02F 1/1362; G02F 1/133345; G02F 1/1368; H01L 27/1288; G02F 2001/136222; H01L 27/1248

(57) ABSTRACT

A thin film transistor (TFT) array substrate and a manufacturing method of same are provided. The TFT array substrate includes a TFT array layer, a color filter layer, and a passivation layer. The color filter layer includes a blue sub-pixel, and the passivation layer includes a passivation layer body and a plurality of protrusions protruding on the passivation layer body. By forming the protrusions of the passivation layer on two side areas of the blue sub-pixel of the color filter layer, a photoresist on the two side areas of the blue sub-pixel is increased, such that a thickness of the passivation layer is uniformized, this reduces chromaticity difference.

### FIELD OF INVENTION

The present disclosure relates to the field of display technologies, and more particularly to a thin film transistor (TFT) array substrate and a manufacturing method of same.

### BACKGROUND OF INVENTION

Liquid crystal displays (LCDs) have many advantages such as having a thin body, power saving, and no radiation, and have been widely used in, for example, LCD televisions (TVs), mobile phones, personal digital assistants (PDAs), computer screens, and laptop screens.

A thin film transistor (TFT) LCD generally includes a color filter, a TFT array substrate, and a liquid crystal layer. The color filter provides red, green, blue colors and is currently formed using a photoresist.

Because of leveling issues of the photoresist, a pattern of an actually fabricated sub-pixel is in bowl shaped, and a width of a recess of the sub-pixel exceeds 0.5 micrometer, such that chromaticity difference between a center position and an edge position of the blue sub-pixel is too large, and the chromaticity difference is greater than 0.004. However, a specification of chromaticity difference is ±0.002, the recess of the sub-pixel leads to poor color of a product, among which the blue sub-pixel is most obvious.

### SUMMARY OF INVENTION

An object of the present disclosure is to provide a thin film transistor (TFT) array substrate and a manufacturing method of same, to solve the problem that a blue sub-pixel of a conventional TFT array substrate is in bowl shaped, and chromaticity difference between a center position and an edge position of the blue sub-pixel is too large, thereby affecting technical issues with product color.

To achieve the above object, an embodiment of the present disclosure provides a thin film transistor (TFT) array substrate including:

a TFT array layer;

a color filter layer disposed on the TFT array layer and including a plurality of color resisting units filled with a red photoresist, a green photoresist, and a blue photoresist to correspondingly form a red sub-pixel, a green sub-pixel, and a blue sub-pixel, wherein a thickness of two side areas of the blue sub-pixel is greater than a thickness of a middle area of the blue sub-pixel;

a passivation layer disposed on the color filter layer and including a passivation layer body covering the color filter layer and a plurality of protrusions protruding on the passivation layer body; and

a pixel electrode layer disposed on the passivation layer;

wherein the protrusions are correspondingly disposed above the two side areas of the blue sub-pixel, a thickness of the protrusions ranges between 0.3 μm and 0.5 μm, and a width of the protrusions ranges from ⅕ to ¼ of a width of the blue sub-pixel.

In an embodiment of the present disclosure, each of the protrusions has a rectangular cross section.

In an embodiment of the present disclosure, material of the passivation layer is soluble polytetrafluoroethylene.

An embodiment of the present disclosure further provides a thin film transistor (TFT) array substrate including:

a TFT array layer;

a color filter layer disposed on the TFT array layer and including a plurality of color resisting units filled with a red photoresist, a green photoresist, and a blue photoresist to correspondingly form a red sub-pixel, a green sub-pixel, and a blue sub-pixel, wherein a thickness of two side areas of the blue sub-pixel is greater than a thickness of a middle area of the blue sub-pixel;

a passivation layer disposed on the color filter layer and including a passivation layer body covering the color filter layer and a plurality of protrusions protruding on the passivation layer body; and

a pixel electrode layer disposed on the passivation layer;

wherein the protrusions are correspondingly disposed above the two side areas of the blue sub-pixel.

In an embodiment of the present disclosure, a thickness of the protrusions ranges between 0.3 μm and 0.5 μm.

In an embodiment of the present disclosure, a width of the protrusions ranges from ⅕ to ¼ of a width of the blue sub-pixel.

In an embodiment of the present disclosure, each of the protrusions has a rectangular cross section.

In an embodiment of the present disclosure, material of the passivation layer is soluble polytetrafluoroethylene.

An embodiment of the present disclosure further provides a method of manufacturing thin film transistor (TFT) array substrate including:

a step S1 of providing a substrate and forming a TFT array layer on the substrate;

a step S2 of forming a plurality of color resisting units on the TFT array layer to obtain a color filter layer, wherein the color resisting units are filled with a red photoresist, a green photoresist, and a blue photoresist to correspondingly form a red sub-pixel, a green sub-pixel, and a blue sub-pixel, wherein a thickness of two side areas of the blue sub-pixel is greater than a thickness of a middle area of the blue sub-pixel;

a step S3 of coating a photoresist on the color filter layer;

a step S4 of patterning the photoresist using a halftone mask to obtain a passivation layer, such that the passivation layer forms a plurality of protrusions corresponding to two side areas of the blue sub-pixel; wherein the passivation layer includes a passivation layer body covering the color filter layer and the protrusions protruding on the passivation layer body; and

a step S5 of forming a pixel electrode layer on the passivation layer.

In an embodiment of the present disclosure, the halftone mask includes a first light transmitting part and a second light transmitting part, a light transmittance of the first light transmitting part is greater than a light transmittance of the second light transmitting part, the photoresist is a negative photoresist, and the step S4 includes:

a step S41 of providing the first light transmitting part on a position of the photoresist correspondingly disposed above the two side areas of the blue sub-pixel, and providing the second light transmitting part on a position of the photoresist correspondingly disposed above other area other than the two side areas of the blue sub-pixel; and

a step S42 of exposing and developing the photoresist using the halftone mask to obtain the passivation layer, the passivation layer including the passivation layer body covering the color filter layer and the protrusions protruding on the passivation layer body.

In an embodiment of the present disclosure, a thickness of the protrusions ranges between 0.3 μm and 0.5 μm.

In an embodiment of the present disclosure, a width of the protrusions ranges from ⅕ to ¼ of a width of the blue sub-pixel.

In an embodiment of the present disclosure, each of the protrusions has a rectangular cross section.

In an embodiment of the present disclosure, material of the passivation layer is soluble polytetrafluoroethylene.

In an embodiment of the present disclosure, the TFT array layer is formed using a photolithography process.

Compared with a TFT array substrate of the prior art, in the TFT array substrate and the manufacturing method of same of the embodiment of the present disclosure, by forming the protrusions of the passivation layer on the two side areas of the blue sub-pixel of the color filter layer, the photoresist on the two side areas of the blue sub-pixel is increased, such that a thickness of the passivation layer is uniformized, this reduces chromaticity difference. In addition, the protrusions can concentrate light scattered by the blue photoresist to reduce loss of light transmittance and solve the problem that a blue sub-pixel of a conventional TFT array substrate is in bowl shaped, and chromaticity difference between a center position and an edge position of the blue sub-pixel is too large, thereby affecting technical issues with product color.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a schematic structural view of a thin film transistor (TFT) array substrate according to an embodiment of the present disclosure.

FIG. 2 is a flowchart of a method of manufacturing a TFT array substrate according to an embodiment of the present disclosure.

FIG. 3 is a schematic diagram of step S1 of a method of manufacturing a TFT array substrate according to an embodiment of the present disclosure.

FIG. 4 is a schematic diagram of step S2 of a method of manufacturing a TFT array substrate according to an embodiment of the present disclosure.

FIG. 5 is a schematic diagram of step S3 of a method of manufacturing a TFT array substrate according to an embodiment of the present disclosure.

FIG. 6 is a schematic diagram of step S4 of a method of manufacturing a TFT array substrate according to an embodiment of the present disclosure.

FIG. 7 is schematic structural view of a mask corresponding to a passivation layer in a method of manufacturing a TFT array substrate according to an embodiment of the present disclosure.

FIG. 8 is a schematic diagram of step S5 of a method of manufacturing a TFT array substrate according to an embodiment of the present disclosure.

### DETAILED DESCRIPTION OF PREFERRED EMBODIMENTS

In the drawings, similar structural units are denoted by same reference numerals. The following description is based on the illustrated specific embodiments of this disclosure, which should not be construed as limiting other specific embodiments not discussed in detail herein.

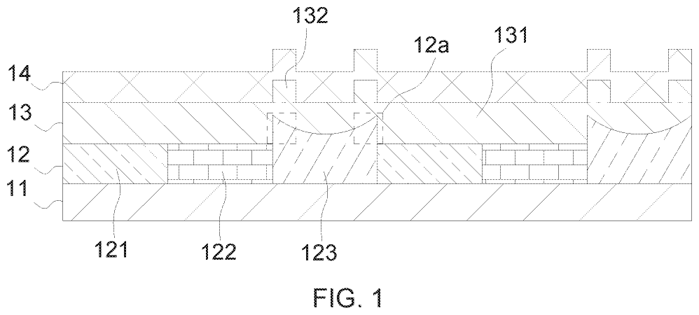

Refer to FIG. 1, a schematic structural view of a thin film transistor (TFT) array substrate according to an embodiment of the present disclosure is provided.

The TFT array substrate of the embodiment of the present disclosure includes a TFT array layer 11, a color filter layer 12, a passivation layer 13, and a pixel electrode layer 14.

In details, the color filter layer 12 is disposed on the TFT array layer 11, and includes a plurality of color resisting units. The color resisting units are filled with a red photoresist, a green photoresist, and a blue photoresist, respectively, and correspondingly form a red sub-pixel 121, a green sub-pixel 122, and a blue sub-pixel 123. A thickness of two side areas 12a of the blue sub-pixel 123 is greater than a thickness of a middle area of the blue sub-pixel 123. The passivation layer 13 is disposed on the color filter layer 12. The passivation layer 13 includes a passivation layer body 131 covering the color filter layer 12 and a plurality of protrusions 132 protruding on the passivation layer body 131. The pixel electrode layer 14 is disposed on the passivation layer 13.

The protrusions 132 are correspondingly disposed above the two side areas 12a of the blue sub-pixel 123.

In the TFT array substrate of the embodiment of the present disclosure, by forming the protrusions 132 of the passivation layer 13 on the two side areas 12a of the blue sub-pixel 123 of the color filter layer 12, the photoresist on the two side areas 12a of the blue sub-pixel 123 is increased, such that a thickness of the passivation layer 13 is uniformized, this reduces chromaticity difference. In addition, the protrusions 132 can concentrate light scattered by the blue photoresist to reduce loss of light transmittance.

In addition, an order of filling the red photoresist, the green photoresist, and the blue photoresist in the color filter layer 12 is not limited.

In an embodiment of the present disclosure, a thickness of the protrusions 132 ranges between 0.3 μm and 0.5 μm. A main function of the protrusions 132 is to increase he photoresist on the two side areas 12a of the blue sub-pixel 123 and to concentrate light scattered by the blue photoresist to reduce loss of light transmittance. When the thickness of the protrusions 132 is less than 0.3 μm, the increased photoresist of the protrusions 132 is insufficient, and there is still a chromaticity difference between the two side areas 12a and the middle area of the blue sub-pixel 123. When the thickness of the protrusions 132 is greater than 0.5 μm, the increased color resistance of the protrusions 132 to the blue sub-pixel 123 is too large, which also causes chromaticity difference between the two side areas 12a and the middle area of the blue sub-pixel 123. Therefore, when the thickness of the protrusions 132 ranges between 0.3 μm and 0.5 μm, the protrusions increases the photoresist on the two side areas 12a of the blue sub-pixel 123 so as to compensate for chromaticity difference between the two side areas 12a and the middle area of the blue sub-pixel 123, thereby achieving uniformity of chromaticity.

In actual production, thicknesses of the two side areas 12a of the blue sub-pixel 123 may be different. An optimal solution is that thicknesses of opposite protrusions 132 are also relatively different, but due to limitations of a current process, the thicknesses of the protrusions 132 adopt same processing scheme, that is, in two convex protrusions with respect to the two side areas of the blue sub-pixel, the protrusion corresponding to a highest thickness in the two side areas is taken as a thickness value of a thickness of an entire protrusion.

Each of the protrusions 132 has a rectangular cross section.

In addition, a width of the protrusions 132 ranges from ⅕ to ¼ of a width of the blue sub-pixel 123. Since a width of a portion where chromaticity difference is greater in the two side areas 12a of the blue sub-pixel 123 from ⅕ to ¼ of a width of the blue sub-pixel 123, other areas are negligible. Therefore, the photoresist on the two side areas 12a of the blue sub-pixel 123 is increased for this range, the width of the protrusions 132 is set to be from ⅕ to ¼ of the width of the blue sub-pixel 123.

In an embodiment of the present disclosure, material of the passivation layer 13 is soluble polytetrafluoroethylene.

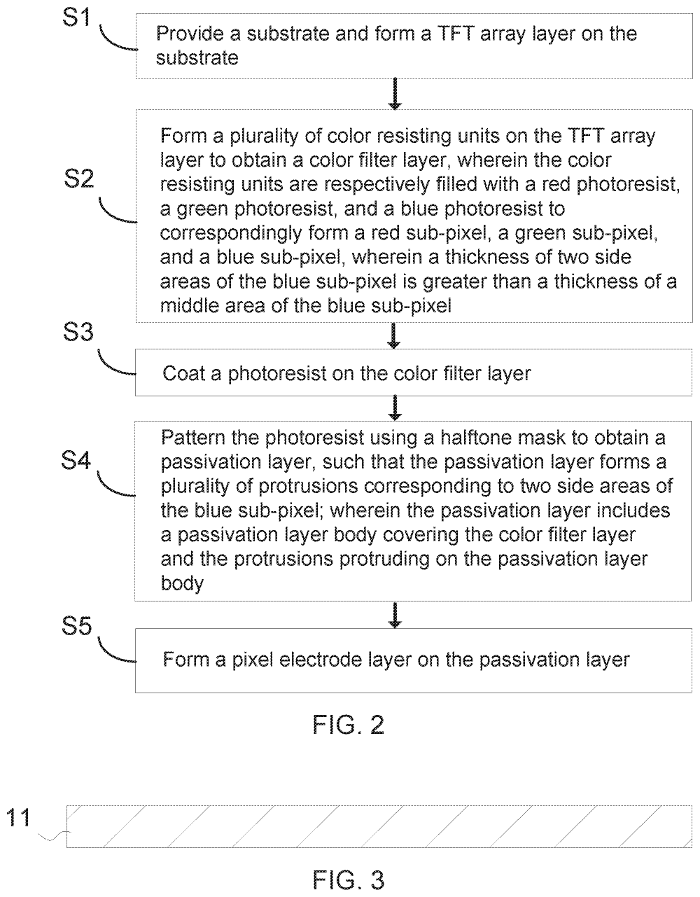

Refer to FIG. 2 to FIG. 8, an embodiment of the present disclosure further relates to a method of manufacturing a TFT array substrate, and steps of the method include:

Step S1 of providing a substrate and forming a TFT array layer on the substrate;

Step S2 of forming a plurality of color resisting units on the TFT array layer to obtain a color filter layer, wherein the color resisting units are respectively filled with a red photoresist, a green photoresist, and a blue photoresist to correspondingly form a red sub-pixel, a green sub-pixel, and a blue sub-pixel, wherein a thickness of two side areas of the blue sub-pixel is greater than a thickness of a middle area of the blue sub-pixel;

Step S3 of coating a photoresist on the color filter layer;

Step S4 of patterning the photoresist using a halftone mask to obtain a passivation layer, such that the passivation layer forms a plurality of protrusions corresponding to two side areas of the blue sub-pixel; wherein the passivation layer includes a passivation layer body covering the color filter layer and the protrusions protruding on the passivation layer body; and

Step S5 of forming a pixel electrode layer on the passivation layer.

In the step S1, referring to FIG. 3, the TFT array layer 11 is formed on a base substrate (not shown) using a series of processes such as film formation, yellow light, and etching.

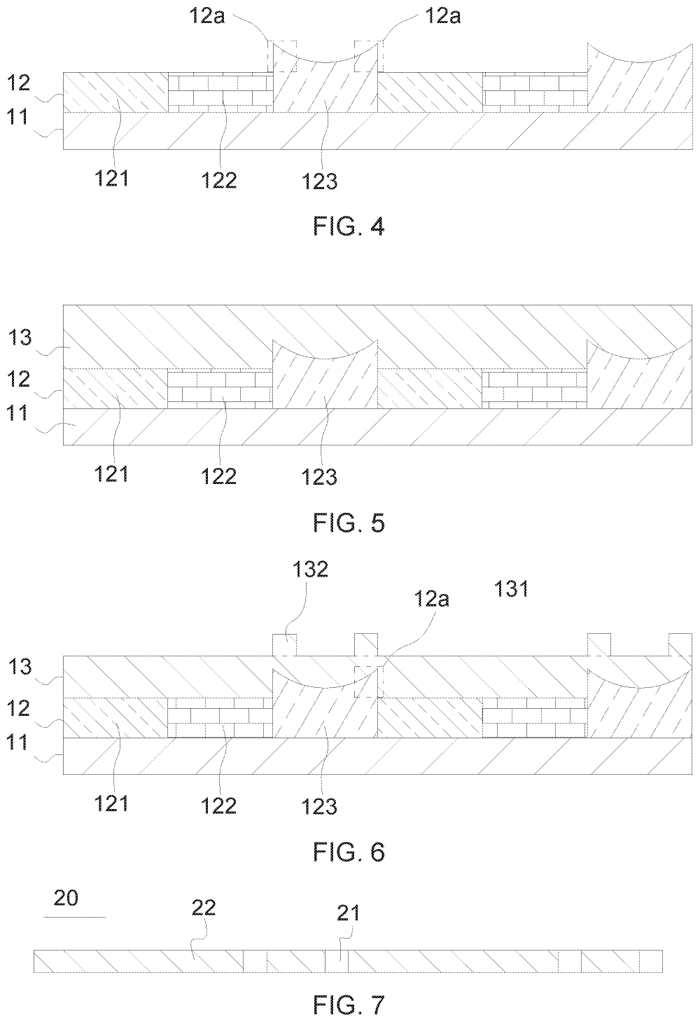

In the step S2, referring to FIG. 4, the color resisting units are sequentially formed on the TFT array layer 11, and a color filter layer 12 is obtained. The color resisting units are filled with a red photoresist, a green photoresist, and a blue photoresist, respectively, and correspondingly form a red sub-pixel 121, a green sub-pixel 122, and a blue sub-pixel 123. A thickness of two side areas 12a of the blue sub-pixel 123 is greater than a thickness of a middle area of the blue sub-pixel 123.

In details, the color filter layer 12 is formed on the TFT array layer 11 using a photolithography process. An order in which the red photoresist, the green photoresist, and the blue photoresist are filled in the color filter layer 12 is not limited.

In the step S3, referring to FIG. 5, a photoresist is coated on the color filter layer 12 for forming a passivation layer 13, wherein the photoresist is a negative photoresist or a positive photoresist. In the embodiment of the present disclosure, a negative photoresist is taken as an example for description.

In the step S4, referring to FIG. 6, the photoresist is patterned using a halftone mask to obtain the passivation layer 13 having portions of different thicknesses. The passivation layer 13 forms protrusions 132 corresponding to two side areas 12a of the blue sub-pixel 123 to increase the photoresist on the two side areas 12a of the blue sub-pixel 123. A height of other areas of the passivation layer 13 is less than a height of an area of the passivation layer 13 corresponding to the two side areas 12a of the blue sub-pixel 123, such that the thickness of the passivation layer 13 corresponding to the entire blue sub-pixel 123 is uniformed, thereby achieving homogenizing chromaticity.

The passivation layer 13 includes a passivation layer body 131 covering the color filter layer 12 and the protrusions 132 disposed on the passivation layer body 131. There is a height difference between the passivation layer body 131 and the protrusions 132, that is, the height of the protrusions 132 is greater than the height of the passivation layer body 131.

A thickness of the protrusions 132 ranges between 0.3 μm and 0.5 μm. A width of the protrusions 132 ranges from ⅕ to ¼ of a width of the blue sub-pixel. Each of the protrusions 132 has a rectangular cross section.

In details, Referring to FIG. 7, a halftone mask 20 includes a first light transmitting part 21 and a second light transmitting part 22. A light transmittance of the first light transmitting part 21 is greater than a light transmittance of the second light transmitting part 22. In the embodiment, the first light transmitting part 21 is completely transparent, and the light transmittance of the second light transmitting part 22 is greater than zero. Step S4 includes the following steps:

Step S41 of providing the first light transmitting part 21 on a position of the photoresist correspondingly disposed above the two side areas 12a of the blue sub-pixel 123, and providing the second light transmitting part 22 on a position of the photoresist correspondingly disposed above other area other than the two side areas 12a of the blue sub-pixel 123; and

Step S42 of exposing and developing the photoresist using the halftone mask 20 to obtain the passivation layer 13, the passivation layer 13 including the passivation layer body 131 covering the color filter layer 12 and the protrusions 132 protruding on the passivation layer body 131.

The photoresist is patterned using the halftone mask 20 to obtain the protrusions 132 corresponding to the passivation layer 132 on the two side areas 12a of the blue sub-pixels 123. On one hand, the photoresist of the two side areas 12a of the blue sub-pixel 123 is increased, such that the thickness of the passivation layer 13 is uniformized, thereby reducing chromaticity difference. On another hand, the protrusions 132 can concentrate light scattered by the blue photoresist (the blue sub-pixel) to reduce loss of light transmittance and improve a color performance of a product.

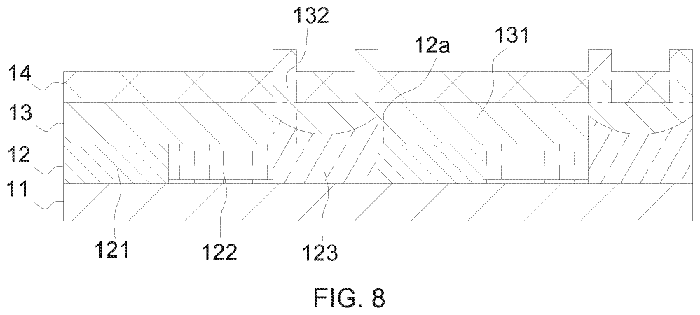

In the step S5, referring to FIG. 8, the pixel electrode layer 14 is formed on the passivation layer 13.

So far, the TFT array substrate has been completed.

An embodiment of the present disclosure also provides a color filter on array (COA) liquid crystal display (LCD) panel having the TFT array substrate of the above embodiment. The COA LCD panel includes an upper substrate, a TFT array substrate, and a liquid crystal layer disposed between the upper substrate and the TFT array substrate.

COA technology is a technique of manufacturing a color resist layer of a color filter substrate on a TFT array substrate, that is, the color filter layer and the TFT array layer are disposed on a same side.

Compared with a TFT array substrate of the prior art, in the TFT array substrate and the manufacturing method of same of the embodiment of the present disclosure, by forming the protrusions of the passivation layer on the two side areas of the blue sub-pixel of the color filter layer, the photoresist on the two side areas of the blue sub-pixel is increased, such that a thickness of the passivation layer is uniformized, this reduces chromaticity difference. In addition, the protrusions can concentrate light scattered by the blue photoresist to reduce loss of light transmittance and solve the problem that a blue sub-pixel of a conventional TFT array substrate is in bowl shaped, and chromaticity difference between a center position and an edge position of the blue sub-pixel is too large, thereby affecting technical issues with product color.

Although the present disclosure has been described in the above embodiments, serial numbers before the embodiments, such as “first”, “second”, etc., are used for convenience of description only, and the order of the embodiments of the present disclosure is not limited. The above embodiments are not intended to limit the present disclosure, and it is understood that many changes and modifications to the described embodiments can be carried out without departing from the scope and the spirit of the disclosure that is intended to be limited only by the appended claims.

What is claimed is:

1. A thin film transistor (TFT) array substrate, comprising:
a TFT array layer;
a color filter layer disposed on the TFT array layer and comprising a plurality of color resisting units filled with a red photoresist, a green photoresist, and a blue photoresist to correspondingly form a red sub-pixel, a green sub-pixel, and a blue sub-pixel, wherein a thickness of two side areas of the blue sub-pixel is greater than a thickness of a middle area of the blue sub-pixel;
a passivation layer disposed on the color filter layer and comprising a passivation layer body covering the color filter layer and a plurality of protrusions protruding on the passivation layer body; and
a pixel electrode layer disposed on the passivation layer;
wherein the protrusions are correspondingly disposed above the two side areas of the blue sub-pixel, a thickness of the protrusions ranges between 0.3 μm and 0.5 μm, and a width of the protrusions ranges from ⅕ to ¼ of a width of the blue sub-pixel.

2. The TFT array substrate according to claim 1, wherein each of the protrusions has a rectangular cross section.

3. The TFT array substrate according to claim 1, wherein material of the passivation layer is soluble polytetrafluoroethylene.

4. A thin film transistor (TFT) array substrate, comprising:
a TFT array layer;
a color filter layer disposed on the TFT array layer and comprising a plurality of color resisting units filled with a red photoresist, a green photoresist, and a blue photoresist to correspondingly form a red sub-pixel, a green sub-pixel, and a blue sub-pixel, wherein a thickness of two side areas of the blue sub-pixel is greater than a thickness of a middle area of the blue sub-pixel;
a passivation layer disposed on the color filter layer and comprising a passivation layer body covering the color filter layer and a plurality of protrusions protruding on the passivation layer body; and
a pixel electrode layer disposed on the passivation layer;
wherein the protrusions are correspondingly disposed above the two side areas of the blue sub-pixel.

5. The TFT array substrate according to claim 4, wherein a thickness of the protrusions ranges between 0.3 μm and 0.5 μm.

6. The TFT array substrate according to claim 4, wherein a width of the protrusions ranges from ⅕ to ¼ of a width of the blue sub-pixel.

7. The TFT array substrate according to claim 4, wherein each of the protrusions has a rectangular cross section.

8. The TFT array substrate according to claim 4, wherein material of the passivation layer is soluble polytetrafluoroethylene.

9. A method of manufacturing thin film transistor (TFT) array substrate, comprising:
a step S1 of providing a substrate and forming a TFT array layer on the substrate;
a step S2 of forming a plurality of color resisting units on the TFT array layer to obtain a color filter layer, wherein the color resisting units are filled with a red photoresist, a green photoresist, and a blue photoresist to correspondingly form a red sub-pixel, a green sub-pixel, and a blue sub-pixel, wherein a thickness of two side areas of the blue sub-pixel is greater than a thickness of a middle area of the blue sub-pixel;
a step S3 of coating a photoresist on the color filter layer;
a step S4 of patterning the photoresist using a halftone mask to obtain a passivation layer, such that the passivation layer forms a plurality of protrusions corresponding to two side areas of the blue sub-pixel; wherein the passivation layer comprises a passivation layer body covering the color filter layer and the protrusions protruding on the passivation layer body; and
a step S5 of forming a pixel electrode layer on the passivation layer.

10. The method of manufacturing the TFT array substrate according to claim 9, wherein the halftone mask comprises a first light transmitting part and a second light transmitting part, a light transmittance of the first light transmitting part is greater than a light transmittance of the second light transmitting part, the photoresist is a negative photoresist, and the step S4 comprises:
a step S41 of providing the first light transmitting part on a position of the photoresist correspondingly disposed above the two side areas of the blue sub-pixel, and providing the second light transmitting part on a position of the photoresist correspondingly disposed above other area other than the two side areas of the blue sub-pixel; and
a step S42 of exposing and developing the photoresist using the halftone mask to obtain the passivation layer, the passivation layer comprising the passivation layer body covering the color filter layer and the protrusions protruding on the passivation layer body.

11. The method of manufacturing the TFT array substrate according to claim 9, wherein a thickness of the protrusions ranges between 0.3 μm and 0.5 μm.

12. The method of manufacturing the TFT array substrate according to claim 9, wherein a width of the protrusions ranges from ⅕ to ¼ of a width of the blue sub-pixel.

13. The method of manufacturing the TFT array substrate according to claim 9, wherein each of the protrusions has a rectangular cross section.

14. The method of manufacturing the TFT array substrate according to claim 9, wherein material of the passivation layer is soluble polytetrafluoroethylene.

15. The method of manufacturing the TFT array substrate according to claim 9, wherein the TFT array layer is formed using a photolithography process.
